(19) United States
(12) Patent Application Publication
(10) Pub. No.: US 2017/0353188 A1
(43) Pub. Date: Dec. 7, 2017

(54) SERIES REGULATOR AND SEMICONDUCTOR INTEGRATED CIRCUIT

(71) Applicant: Synaptics Japan GK, Tokyo (JP)

(72) Inventors: Yutaka SAEKI, Tokyo (JP); Taisuke KOSHINO, Tokyo (JP)

(21) Appl. No.: 15/481,148

(22) Filed: Apr. 6, 2017

(30) Foreign Application Priority Data
Jun. 2, 2016 (JP) 2016110878

(51) Int. Cl. H03K 19/0185; G05F 1/575; H03F 3/45

(52) U.S. Cl. CPC H03K 19/018507; H03F 3/45246; G05F 1/575; H03F 2203/45274

(57) ABSTRACT

The series regulator has: a differential amplifier; a level shifter including a level shift transistor with a drain connected to a gate; and a source follower including an output transistor. The differential amplifier includes an amplification stage having a non-inverting input terminal for input of a reference voltage, an inverting input terminal for input of a feedback voltage, and an amplifier output terminal. The differential amplifier has a DC operation point where an error of an output voltage at the amplifier output terminal to an input voltage to the non-inverting input terminal is equal to or under a gate-source voltage of an input transistor, and a follower output terminal of the source follower is feedback-connected to the inverting input terminal. The level shifter performs a level shift to make an output voltage of the source follower coincident with the voltage at the amplifier output terminal of the differential amplifier.

### CROSS-REFERENCE TO RELATED APPLICATIONS

The present application claims priority to Japanese application JP 2016-110878 filed on Jun. 2, 2016, the content of which is hereby incorporated by reference into this application in its entirety.

### BACKGROUND

The present disclosure relates to a series regulator which is provided on a semiconductor integrated circuit, and it relates to a technique useful in application to e.g. a power supply circuit for producing a source voltage of a logic circuit.

In many cases, a series regulator provided on a semiconductor integrated circuit has a final stage including a source follower for speeding up the current load response of an output voltage, and two amplification stages preceding it. For instance, the Japanese Unexamined Patent Application Publication No. JP-A-2000-284843 discloses such a series regulator. The series regulator has a basic circuit structure in which a source-grounded circuit is provided at an output of a differential amplifier as the second step amplification stage, and a source follower receives its drain output. As shown in JP-A-2000-284843, a series regulator of this type has a stabilization capacitance of the order of a micro farad (μF) outside a semiconductor integrated circuit for the purpose of ensuring the stability of an output voltage. The number of externally attached parts rises with the increase in the number of series regulators (RGL) provided on a semiconductor integrated circuit (LSI) as shown in FIG. 11, by example. This is because a stabilization capacitance (C) is required for each series regulator.

### SUMMARY

Techniques are described for a speedup of the load response of an output voltage of a series regulator. FIG. 12 shows, by example, a series regulator of a logic power supply circuit for supplying an operation power source to, e.g., a logic circuit of a display driver as a series regulator. In the series regulator, a final stage is formed by a source follower in order to speed up a current load response of an output voltage, and its amplifier has a general two-step amplification structure and consists of: a differential amplifier forming the first amplification stage, and having a non-inverting input terminal (+) to which a reference voltage is input as an input voltage VIN and an inverting input terminal (−) to which an output voltage VOUT is fed back; and a source-grounded amplifier forming the second step amplification stage. Consequently, in the amplifier, a delay corresponding to the two amplification stages is caused in the response speed of the two-step amplifier. Without an external stabilization capacitance, the output voltage of the series regulator cannot be controlled stably against a high-speed current load fluctuation.

In the case of an amplifier arranged so that its amplification stage is formed by only one stage including a differential amplifier as shown in FIG. 13 in order to increase the response speed of the amplifier, the input voltage becomes VIN≠VOUT because of a small amplification factor of the amplifier and thus, an input voltage of the series regulator is not incident with its output voltage. Specifically, in a two-input differential amplifier as shown in FIG. 14, input voltages to non-inverting and inverting input terminals of the amplifier are both VIN, i.e. equal to each other with no feedback. Supposing that the output voltage at that time is V0, VIN≠V0 holds in most conditions, provided that it depends on the voltage of the input voltage VIN. Supposing that the voltage difference between the input voltage VIN and the output voltage V0 is given by ΔV=VIN−V0, the difference voltage ΔV can be about 4 V if the amplifier is e.g. 5V-range working type one.

In case that the amplifier shown in FIG. 14 is feedback-controlled, the following equation in regard to the amplification factor (i.e. the degree of voltage amplification) Av of the amplifier holds: ΔV=VOUT−V0=Av(VIN−VOUT), which is noted in FIG. 14. In the case of two-step amplification as shown in FIG. 12, the amplification factor becomes about 10,000 times, which largely influences the voltage difference ΔV. If the variable is replaced with the value, the equation becomes as follows: ΔV=VOUT−V0=4 V=10000×(VIN−VOUT); and VIN−VOUT=4 V/10000=0.4 mV. Then, the following relation is obtained: VIN≈VOUT. On the other hand, if the amplification factor is just about 100 times as in the case of one-step amplification of FIG. 13, the equation is as follows: ΔV=VOUT−V0=4 V=100×(VIN−VOUT); and VIN−VOUT=4 V/100=40 mV. Then, the following relation is obtained: VIN≠VOUT. In addition, ΔV is caused to fluctuate by the input voltage VIN and the source voltage and as such, the series regulator cannot output a desired voltage for an output VOUT.

As described above, in a series regulator of which the amplifier is a two-step amplification one, a delay caused by two amplification stages arises in the response speed of the amplifier, and the output voltage of the series regulator cannot be stabilized against a high-speed current load fluctuation without a stabilization capacitance provided outside it. Even if the amplifier is made a one-step amplification amplifier for increasing the response speed, the input voltage of the series regulator does not become equal to the output voltage thereof because of a small amplification factor of the amplifier.

It is one object of the disclosure to achieve a suitable load responsiveness in the output voltage of a series regulator even with a stabilization capacitance reduced, i.e. to easily ensure the stability of the output against a current fluctuation.

The above and other objects of the disclosure, and novel features thereof will become apparent from the description hereof and the accompanying diagrams.

Of the embodiments disclosed in the present application, the representative embodiments will be briefly outlined below. It is noted that the reference numerals or character strings in parentheses in the subsequent paragraphs, which are noted for reference to the diagrams, are just exemplifies for easier understanding.

### [1] Series Regulator having a One-Step Amplification Differential Amplifier, a Level Shifter and a Source Follower

A series regulator (1) includes: a differential amplifier (2); a level shifter (3, 3_A, 3_B, 5, 5_A, 7, 7_A) including a level shift transistor (MN7, MP12, MN15, MP16) with a drain connected to its own gate; and a source follower (4, 4_A, 4_B, 6, 6_A, 8) including an output transistor (MN10, MP13, MN17, MP18). The differential amplifier includes an amplification stage having a non-inverting input terminal (T1) for inputting a reference voltage (VIN), an inverting input terminal (T2) for inputting a feedback voltage (VOUT), and an amplifier output terminal (T3). The differential amplifier has a DC operation point at which an error of an output voltage (PVOUT) at the amplifier output terminal to an input voltage (VIN) to the non-inverting input terminal is equal to or less than a voltage between a gate and a source (VGSP, VGSN) of an input transistor, and a follower output terminal of the source follower is feedback-connected to the inverting input terminal. The level shifter accepts input of an output voltage from the amplifier output terminal at a source of the level shift transistor, and outputs a gate voltage thereof as a shift voltage. The source follower receives the shift voltage from the level shifter at a gate of the output transistor, and a source of the output transistor makes the follower output terminal (T4).

According to this embodiment, the one-step amplification differential amplifier is smaller than a two-step amplification differential amplifier in amplifying action delay to load fluctuation. Further, the differential amplifier has a DC operation point at which an error of an output voltage at the amplifier output terminal to an input voltage to the non-inverting input terminal is equal to or less than a voltage between the gate and source of the input transistor. The DC operation point is hard to fluctuate depending on input voltages to the input terminal T1, T2 and the source voltage (VDD2). Therefore, even if the differential amplifier is a one-step amplification amplifier, it can output a voltage small in error to the reference voltage (VIN) at the amplifier output terminal (T3). The voltage at the follower output terminal (T4) can be obtained based on a voltage (PVOUT) at the amplifier output terminal, which has been passed through the level shifter and the source follower. In this way, a desired voltage small in error to the reference voltage can be output at the follower output terminal. Therefore, a required output voltage to an input voltage to the series regulator can be formed with a high-speed load responsiveness without adding a large stabilization capacitance outside a semiconductor integrated circuit. The stabilization capacitance to be connected to the follower output terminal can be made smaller infinitely and therefore, the stabilization capacitance can be provided in the semiconductor integrated circuit. The differential amplifier contributes to the achievement of a low power consumption because of being composed of a one-step amplification amplifier.

### [2] Embodiment of the Differential Amplifier

In the series regulator as described in [1], the differential amplifier has: a p-channel type first input transistor (MP1) and an n-channel type second input transistor (MN2) of which gates are commonly connected to the non-inverting input terminal; a p-channel type third feedback input transistor (MP3) and an n-channel type fourth feedback input transistor (MN4) of which gates are commonly connected to the inverting input terminal; a first load (MN5) connected to a drain of the first input transistor, and linked to a low-potential side power source; and a second load (MP6) connected to a drain of the second input transistor, and linked to a high-potential side power source. A common drain of the third and fourth feedback input transistors makes the amplifier output terminal.

In this embodiment, if it is supposed that a voltage between the gate and source of the first input transistor (MP1) is VGSP1, and a voltage between the drain and source thereof is VDSP1, and a voltage between the gate and source of the second input transistor (MN2) is VGSN2 and a voltage between the drain and source thereof is VDSN2, the DC operation point VT3 of the amplifier output terminal (T3) satisfies the following relation: VIN−(VGSN2−VDSN2)<VT3<VIN+(VGSP1−VDSP1). Therefore, a voltage small in error to the reference voltage (VIN) can be output at the amplifier output terminal (T3).

### [3] Embodiment of the Differential Amplifier

In the series regulator as described in [1], the differential amplifier has: a p-channel type first input transistor (MP1) and an n-channel type second input transistor (MN2) of which gates are commonly connected to the non-inverting input terminal; a p-channel type third input transistor (MP3) and an n-channel type fourth input transistor (MN4) of which gates are commonly connected to the inverting input terminal; a diode-connected n-channel type fifth load transistor (MN5) connected to a drain of the first input transistor, and linked to a low-potential side power source; and a diode-connected p-channel type sixth load transistor (MP6) connected to a drain of the second input transistor, and linked to a high-potential side power source. A common drain of the third and fourth feedback input transistors makes the amplifier output terminal.

This embodiment brings about the same effect as that achieved by the embodiment described in [2].

### [4] Level Shift Transistor of n-channel Type

In the series regulator as described in [2], the level shifter (3) includes an n-channel type seventh transistor (MN7) disposed between a current source (10) linked to a high-potential side power source (VDD2), and a current source (11) linked to a low-potential side power source (GND); the seventh transistor has a drain connected to its own gate, and a source connected to the amplifier output terminal; and a drain voltage of the seventh transistor makes the shift voltage.

According to this embodiment, the level shifter shifts up a voltage (PVOUT) at the amplifier output terminal by a voltage between the gate and source of the seventh transistor, and outputs the resultant voltage.

### [5] Level Shift Transistor of n-channel Type

In the series regulator as described in [3], the level shifter (3_A) includes an n-channel type eighth current source transistor (MN8) sharing a gate with the fifth load transistor, and linked to a low-potential side power source (GND), a p-channel type ninth current source transistor (MP9) sharing a gate with the sixth load transistor, and linked to a high-potential side power source (VDD2), and an n-channel type seventh transistor (MN7) disposed between the eighth and ninth current source transistors; the seventh transistor has a drain connected to its own gate, and a source connected to the amplifier output terminal; and a drain voltage of the seventh transistor makes the shift voltage.

According to this embodiment, the level shifter shifts up a voltage (PVOUT) at the amplifier output terminal by a voltage between the gate and source of the seventh transistor, and outputs the resultant voltage. Further, the eighth and ninth current source transistors each form a current mirror circuit in combination with the corresponding fifth and sixth load transistors of the differential amplifier 2, which works so as to increase the amplification factor of the differential amplifier.

### [6] Source Follower Transistor of n-channel Type

In the series regulator as described in [4], the source follower (4) includes an n-channel type tenth transistor (MN10) having a source connected to a current source (12) linked to a low-potential side power source (GND); the tenth transistor has a gate commonly connected with the gate of the seventh transistor; and the source of the tenth transistor makes the follower output terminal.

This embodiment allows the source follower to receive a drain voltage of the seventh transistor of the level shifter at the gate of the tenth MOS transistor, and to output a voltage coincident with a voltage (PVOUT) at the amplifier output terminal (T3) at the source of the tenth MOS transistor. This source follower is suitable for a case in which an output function of a so-called source-driving type is required.

### [7] Source Follower Transistor of n-channel Type

In the series regulator as described in [5], wherein the source follower (4_A) includes an n-channel type eleventh current source transistor (MN11) sharing a gate with the fifth load transistor, and linked to a low-potential side power source, and an n-channel type tenth transistor (MN10) having a source connected to a drain of the eleventh current source transistor; the tenth transistor has a gate commonly connected with the gate of the seventh transistor; and the source of the tenth transistor makes the follower output terminal (T4).

This embodiment allows the source follower to receive a drain voltage of the seventh transistor of the level shifter at the gate of the tenth MOS transistor, and to output a voltage coincident with a voltage (PVOUT) at the amplifier output terminal (T3) at the source of the tenth MOS transistor. This source follower is suitable for a case in which an output function of a so-called source-driving type is required.

### [8] Level Shift Transistor of p-channel Type

In the series regulator as described in [2], the level shifter (5) includes a p-channel type twelfth transistor (MP12) disposed between a current source (10) linked to a high-potential side power source (VDD2), and a current source (11) linked to a low-potential side power source (GND); the twelfth transistor has a drain connected to its own gate, and a source connected to the amplifier output terminal; and a drain voltage of the twelfth transistor makes the shift voltage.

According to this embodiment, the level shifter shifts down a voltage (PVOUT) at the amplifier output terminal by a voltage between the gate and source of the twelfth transistor, and outputs the resultant voltage.

### [9] Level Shift Transistor of p-channel Type

In the series regulator as described in [3], the level shifter (5_A) includes: an n-channel type eighth current source transistor (MN8) sharing a gate with the fifth load transistor, and linked to a low-potential side power source (GND); a p-channel type ninth current source transistor (MP9) sharing a gate with the sixth load transistor, and linked to the high-potential side power source (VDD2); and a p-channel type twelfth transistor (MP12) disposed between the eighth and ninth current source transistors. The twelfth transistor has a drain connected to its own gate, and a source connected to the amplifier output terminal; and a drain voltage of the twelfth transistor makes the shift voltage.

According to this embodiment, the level shifter shifts down a voltage (PVOUT) at the amplifier output terminal by a voltage between the gate and source of the twelfth transistor and outputs the resultant voltage. Further, the eighth and ninth current source transistors each form a current mirror circuit in combination with the corresponding fifth and sixth load transistors of the differential amplifier 2, which works so as to increase the amplification factor of the differential amplifier.

### [10] Source Follower Transistor of p-channel Type

In the series regulator as described in [8], the source follower (6) includes a p-channel type thirteenth transistor (MP13) having a source connected to a current source (13) linked to a high-potential side power source (VDD1); the thirteenth transistor has a gate commonly connected with the gate of the twelfth transistor; and the source of the thirteenth transistor makes the follower output terminal (T4).

This embodiment allows the source follower to receive a drain voltage of the twelfth transistor of the level shifter at the gate of the thirteenth MOS transistor, and to output a voltage coincident with a voltage (PVOUT) at the amplifier output terminal (T3) at the source of the thirteenth MOS transistor. This source follower is suitable for a case in which an output function of a so-called sink-driving type is required.

### [11] Source Follower Transistor of p-channel Type

In the series regulator as described in [9], the source follower (6_A) includes a p-channel type fourteenth current source transistor (MP14) sharing a gate with the sixth load transistor, and linked to a high-potential side power source (VDD1), and a p-channel type thirteenth transistor (MP13) having a source connected to a drain of the fourteenth current source transistor; the thirteenth transistor has a gate commonly connected with the gate of the twelfth transistor; and the source of the thirteenth transistor makes the follower output terminal (T4).

This embodiment allows the source follower to receive a drain voltage of the twelfth transistor of the level shifter at the gate of the thirteenth MOS transistor, and to output a voltage coincident with a voltage (PVOUT) at the amplifier output terminal (T3) at the source of the thirteenth MOS transistor. This source follower is suitable for a case in which an output function of a so-called sink-driving type is required.

### [12] CMOS Level Shift Transistor

In the series regulator as described in [2], the level shifter (7) includes an n-channel type fifteenth transistor (MN15) and a p-channel type sixteenth transistor (MP16) which are connected in series to each other through a source common thereto between a current source (10) linked to a high-potential side power source (VDD2) and a current source (11) linked to a low-potential side power source (GND); the fifteenth transistor has a drain connected to its own gate, and the sixteenth transistor has a drain connected to its own gate; the common source of the fifteenth and sixteenth transistors is connected to the amplifier output terminal (T3); and a drain voltage of each of the fifteenth and sixteenth transistors makes the shift voltage.

According to this embodiment, the level shifter outputs: a voltage resulting from the upshift of a voltage (PVOUT) at the amplifier output terminal by a voltage between the gate and source of the fifteenth transistor; and a voltage resulting from the downshift thereof by a voltage between the gate and source of the sixteenth transistor.

### [13] CMOS Level Shift Transistor

In the series regulator as described in [3], the level shifter (7_A) includes an n-channel type eighth current source transistor (MN8) sharing a gate with the fifth load transistor, and linked to the low-potential side power source (GND), a p-channel type ninth current source transistor (MP9) sharing a gate with the sixth load transistor, and linked to the high-potential side power source (VDD2), and an n-channel type fifteenth transistor (MN15) and a p-channel type sixteenth transistor (MP16) which are connected in series to each other through a source common thereto between the eighth and ninth current source transistors; the fifteenth transistor has a drain connected to its own gate, and the sixteenth transistor has a drain connected to its own gate; the common source of the fifteenth and sixteenth transistors is connected to the amplifier output terminal (T3); and a drain voltage of each of the fifteenth and sixteenth transistors makes the shift voltage.

According to this embodiment, the level shifter outputs: a voltage resulting from the upshift of a voltage (PVOUT) at the amplifier output terminal by a voltage between the gate and source of the fifteenth transistor; and a voltage resulting from the downshift of the voltage by a voltage between the gate and source of the sixteenth transistor. Further, the eighth and ninth current source transistors each form a current mirror circuit in combination with the corresponding fifth and sixth load transistors of the differential amplifier 2, which works so as to increase the amplification factor of the differential amplifier.

### [14] CMOS Source Follower Transistor

In the series regulator as described in [12], wherein the source follower (8) includes an n-channel type seventeenth transistor (MN17) and a p-channel type eighteenth transistor (MP18) which are connected in series to each other through a source common thereto; the seventeenth transistor is connected to the gate of the fifteenth transistor, and the eighteenth transistor is connected to the gate of the sixteenth transistor; and the common source of the seventeenth and eighteenth transistors makes the follower output terminal (T4).

This embodiment allows the source follower to receive a drain voltage of the fifteenth transistor of the level shifter at the gate of the seventeenth MOS transistor, and to output a voltage coincident with a voltage (PVOUT) at the amplifier output terminal (T3) at the source of the seventeenth MOS transistor, and allows the source follower to receive a drain voltage of the sixteenth transistor of the level shifter at the gate of the eighteenth MOS transistor and to output a voltage coincident with a voltage (PVOUT) at the amplifier output terminal (T3) at the source of the eighteenth MOS transistor. This source follower forms an output circuit having both of so-called source-driving and sink-driving functions. So, the series regulator is superior in responsiveness to a load fluctuation to a series regulator having an output characteristic according to only one of the sink-driving and source-driving functions.

### [15] CMOS Source Follower Transistor

In the series regulator as described in [13], the source follower (8) includes an n-channel type seventeenth transistor (MN17) and a p-channel type eighteenth transistor (MP18) which are connected in series to each other through a source common thereto; the seventeenth transistor is connected to the gate of the fifteenth transistor, and the eighteenth transistor is connected to the gate of the sixteenth transistor; and the common source of the seventeenth and eighteenth transistors makes the follower output terminal (T4).

This embodiment brings about the same effect as that achieved by the embodiment described in [14].

### [16] Distribution Layout in the Source Follower

In the series regulator as described in [1], the output transistor of the source follower includes a plurality of output transistors (MN1_1 to MN10_m) having a common gate; the plurality of output transistors receive the shift voltage from the level shifter at the common gate; and a common source of the plurality of output transistors makes the follower output terminal (T4).

According to this embodiment, the voltage (VOUT) at the follower output terminal (T4) depends on the gate-source voltage of the plurality of output transistors, and it does not influenced by the voltage drop in high-potential side source voltage (VDD1) owing to the wiring resistance of the source line. Therefore, there is no influence on the performance even if the output transistor of the source follower is distributed as required.

### [17] High-Potential Side Source Voltage

In the series regulator as described in [1], a source voltage (VDD2) of a high-potential side power source of the differential amplifier and the level shifter is made higher than a source voltage (VDD1) of a high-potential side power source of the source follower.

According to this embodiment, the voltage range of the output voltage (VOUT) of the source follower can be widened.

### [18] LSI

A semiconductor integrated circuit (30) includes a logic circuit (32), and a series regulator (1) for supplying an operation power source to the logic circuit on a semiconductor substrate. The series regulator includes: a differential amplifier (2); a level shifter (3, 3_A, 3_B, 5, 5_A, 7, 7_A) including a level shift transistor (MN7, MP12, MN15, MP16) with a drain connected to its own gate; and a source follower (4, 4_A, 4_B, 6, 6_A, 8) including an output transistor (MN10, MP13, MN17, MP18). The differential amplifier includes an amplification stage having a non-inverting input terminal (T1) for inputting a reference voltage (VIN), an inverting input terminal (T2) for inputting a feedback voltage (VOUT), and an amplifier output terminal (T3); the differential amplifier has a DC operation point at which an error of an output voltage (PVOUT) at the amplifier output terminal to an input voltage(VIN) to the non-inverting input terminal is equal to or less than a voltage between the gate and source (VGSP, VGSN) of an input transistor; and a follower output terminal of the source follower is feedback-connected to the inverting input terminal. The level shifter accepts input of an output voltage at the amplifier output terminal at a source of the level shift transistor, and outputs a gate voltage thereof as a shift voltage. The source follower receives the shift voltage from the level shifter at a gate of the output transistor; and a source of the output transistor makes the follower output terminal (T4). A voltage at the follower output terminal makes the operation power source.

This embodiment brings about the same effect as that achieved by the embodiment described in [1]. Further, it eliminates the need for a capacitive element to be externally attached for the series regulator operable to supply an operation power source to the logic circuit, and enables the supply of a stable operation power source even with a load fluctuation in the logic circuit.

### [19] First Embodiment of the Differential Amplifier

In the semiconductor integrated circuit as described in [18], the differential amplifier has: a p-channel type first input transistor (MP1) and an n-channel type second input transistor (MN2) of which gates are commonly connected to the non-inverting input terminal; a p-channel type third input transistor (MP3) and an n-channel type fourth input transistor (MN4) of which gates are commonly connected to the inverting input terminal; a first load (MN5) connected to a drain of the first input transistor, and linked to a low-potential side power source; and a second load (MP6) connected to a drain of the second input transistor, and linked to a high-potential side power source. A common drain of the third and fourth feedback input transistors makes the amplifier output terminal.

This embodiment brings about the same effect as that achieved by the embodiment described in [2].

### [20] Distribution Layout in the Source Follower

In the semiconductor integrated circuit as described in [18], the output transistor of the source follower includes a plurality of output transistors (MN10_1 to MN10_m) having a common gate; the plurality of output transistors receive the shift voltage from the level shifter at the common gate; and a common source of the plurality of output transistors makes the follower output terminal (T4).

This embodiment brings about the same effect as that achieved by the embodiment described in [16]. Especially, a power source can be stably supplied to each circuit part without an undesired voltage drop even in the logic circuit large in circuit scale.

The effect achieved by the representative embodiments disclosed in the present application will be briefly described below.

Good load responsiveness can be achieved in an output voltage of a series regulator even with a stabilization capacitance reduced, and the output stability against current fluctuation can be ensured readily.

### BRIEF DESCRIPTION OF THE DRAWINGS

FIG. 1 is a circuit diagram showing a source-driving type series regulator, which is an embodiment of the series regulator of the disclosure;

FIG. 2 is a circuit diagram showing an embodiment of a differential amplifier in the series regulator of FIG. 1;

FIG. 3 is a circuit diagram showing an example in which current sources of the level shifter and source follower in FIGS. 1 and 2 are embodied;

FIG. 4 is a circuit diagram showing a sink-driving type series regulator which is another embodiment of the series regulator of the disclosure;

FIG. 5 is a circuit diagram showing an example in which current sources of the level shifter and source follower in FIG. 4 are embodied;

FIG. 6 is a circuit diagram showing a source-driving and sink-driving type series regulator which is still another embodiment of the series regulator of the disclosure;

FIG. 7 is a circuit diagram showing an example in which current sources of the level shifter and source follower in FIG. 6 are embodied;

FIG. 8 is a circuit diagram showing a series regulator in which the source follower is distributed, which is still another embodiment of the series regulator of the disclosure;

FIG. 9 is a block diagram showing an embodiment of a display driver including a logic power supply circuit to which the series regulator of the disclosure is applied;

FIG. 10 is a frequency characteristic diagram showing, by example, the difference between the series regulator of the disclosure and a series regulator utilizing a two-step amplifier in the frequency characteristic of an output voltage;

FIG. 11 is a block diagram showing, as a comparative example, the series regulator utilizing a two-step amplifier with stabilization capacitances externally attached thereto;

FIG. 12 is a circuit diagram showing, as a comparative example, a circuit structure of the series regulator utilizing a two-step amplifier;

FIG. 13 is a circuit diagram showing, as a comparative example, a circuit structure of a series regulator arranged so that a source follower receives an output of a one-step amplifier; and

FIG. 14 is an explanatory diagram for consideration on input and output characteristics of the differential amplifier.

### DETAILED DESCRIPTION

FIG. 1 shows a source-driving type series regulator which is an embodiment of the series regulator of the disclosure. The series regulator 1 of FIG. 1 includes: a differential amplifier 2; a level shifter 3 including a seventh transistor MN7 of an n-channel type, as an embodiment of the level shift transistor with its drain connected to the gate; and a source follower 4 including a tenth transistor MN10 of an n-channel type as an embodiment of the output transistor. Although no special restriction is intended, the transistors each refer to a MOS (Metal-Oxide-Semiconductor) transistor which is classified into MIS (Metal-Insulated-Semiconductor) in the description below.

In the level shifter 3, the seventh transistor MN7 is disposed between a current source 10 linked to a source voltage VDD2 serving as a high-potential side power source, and a current source 11 linked to the ground GND serving as a low-potential side power source; the drain of the seventh transistor MN7 is connected to its own gate; the amplifier output terminal T3 of the differential amplifier 2 is connected to the source of the seventh transistor MN7; and the drain voltage of the seventh transistor MN7 is output as a shift voltage. The level shifter 3 shifts up, by a voltage between the gate and source of the seventh transistor MN7, the voltage PVOUT at the amplifier output terminal T3, and outputs the resultant voltage.

In the source follower 4, the source of a tenth transistor MN10 is connected to a current source 12 linked to the ground GND serving as a low-potential side power source; the gate of the tenth transistor MN10 is commonly connected to the gate of the seventh transistor MN7; and the source of the tenth transistor MN10 is made a follower output terminal T4. The level shifter 3 is mounted to make the output voltage VOUT of the source follower 4 equal to the voltage PVOUT at the amplifier output terminal T3 of the differential amplifier 2. The source follower 4 receives the drain voltage of the seventh transistor MN7 of the level shifter 3 at its gate, and it is capable of outputting a voltage coincident with the voltage PVOUT of the amplifier output terminal T3 at the source of the tenth transistor MN10. The source follower is suitable for a case in which an output function of a so-called source-driving type is required.

The differential amplifier 2 is composed of a one-step amplifier which has: a non-inverting input terminal T1 to input a reference voltage VIN as an input voltage to; an inverting input terminal T2 to input the output voltage VOUT of the series regulator 1 as a feedback voltage to; and the amplifier output terminal T3. Especially the differential amplifier 2 has a DC operation point at which the error of the output voltage PVOUT at the amplifier output terminal T3 to the input voltage VIN to the non-inverting input terminal T1 is equal to or less than a voltage between the gate and source of the input transistor; the follower output terminal T4 of the source follower is feedback-connected to the inverting input terminal T2.

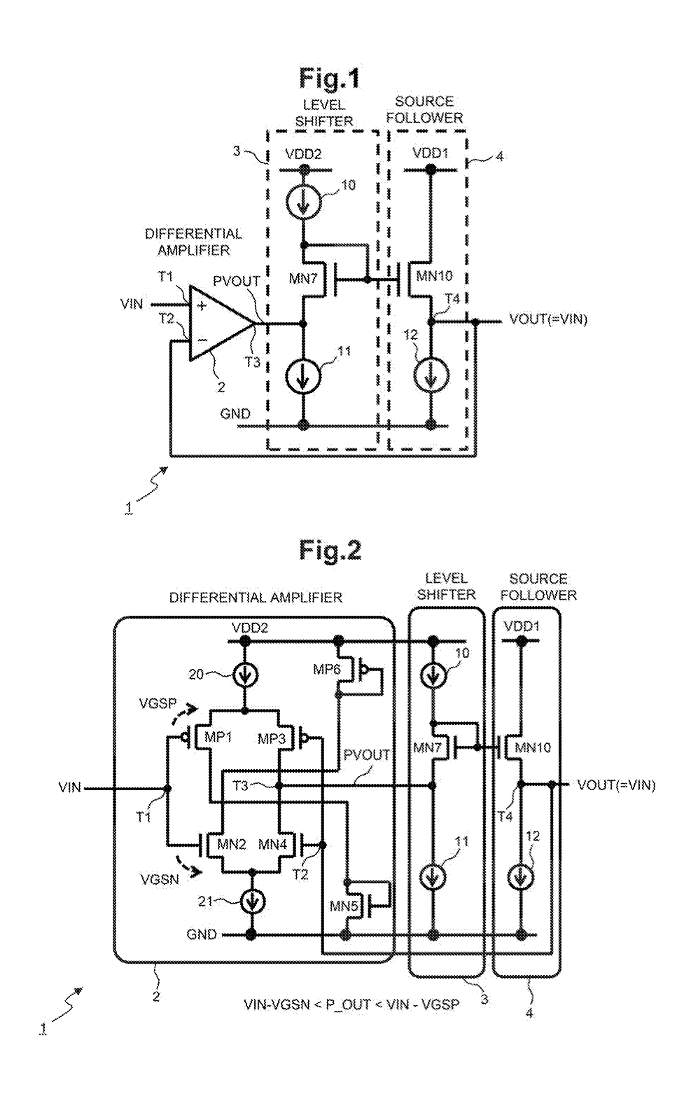

More specifically, as shown by FIG. 2, by example, the differential amplifier 2 has: a p-channel type first input transistor MP1 and an n-channel type second input transistor MN2 with their gates commonly connected to the non-inverting input terminal T1; a p-channel type third feedback input transistor MP3 and an n-channel type fourth feedback input transistor MN4 with their gates commonly connected to the inverting input terminal T2; an n-channel type fifth load transistor MN5 in a diode-connection form, serving as a first load, connected to the drain of the first input transistor MP1, and linked to the ground GND, which is a low-potential side power source; and a p-channel type sixth load transistor MP6 in a diode-connection form, serving a second load, connected to the drain of the second input transistor MN2, and linked to the source voltage VDD2, which is a high-potential side power source. The common drain of the third feedback input transistor MP3 and the fourth feedback input transistor MP4 makes the amplifier output terminal T3.

Supposing that in the differential amplifier 2, the voltage between the gate and source of the first input transistor MP1 is VGSP1, the voltage between the drain and source thereof is VDSP1, the voltage between the gate and source of the second input transistor MN2 is VGSN2, and the voltage between the drain and source thereof is VDSN2, the voltage PVOUT at the DC operation point of the amplifier output terminal (T3) satisfies the following condition: VIN−(VGSN2−VDSN2)<PVOUT<VIN+(VGSP1−VDSP1). Therefore, a voltage with a small error to the input voltage VIN can be output at the amplifier output terminal T3. On condition that VGSN2=VGSP1=0.7 V and VDSN2=VDSP1=0.2 V, for instance, the voltage difference ΔV between VIN and VPOUT is kept down about ±0.5 V in the embodiment of FIG. 2, and the voltage does not largely depend on the input voltage and the source voltage of the amplifier.

In the case of performing the feedback control on the amplifier as described with reference to FIG. 14 in consideration of this, the following equation shown in FIG. 4 holds according to the amplification factor (i.e. the degree of voltage amplification) Av of the amplifier: ΔV=VOUT−V0=Av(VIN−VOUT). The amplification factor of the one-step amplification differential amplifier 2 of FIG. 2 is small in comparison to that of a two-step amplifier; if it is supposed to be e.g. about 100 times, the voltage difference ΔV is as follows: ΔV=VOUT−V0=0.5 V=100×(VIN−VOUT). Therefore, VIN−VOUT=0.5 V/100=5 mV and thus VIN≈VOUT. The output voltage V0 of the differential amplifier 2 does not largely fluctuate according to the input voltage VIN and the source voltage VVD2 as described above and therefore, the series regulator 1 can output, as the output voltage VOUT, a desired voltage, i.e. an output voltage VOUT which substantially coincides with a voltage set as the reference voltage VIN.

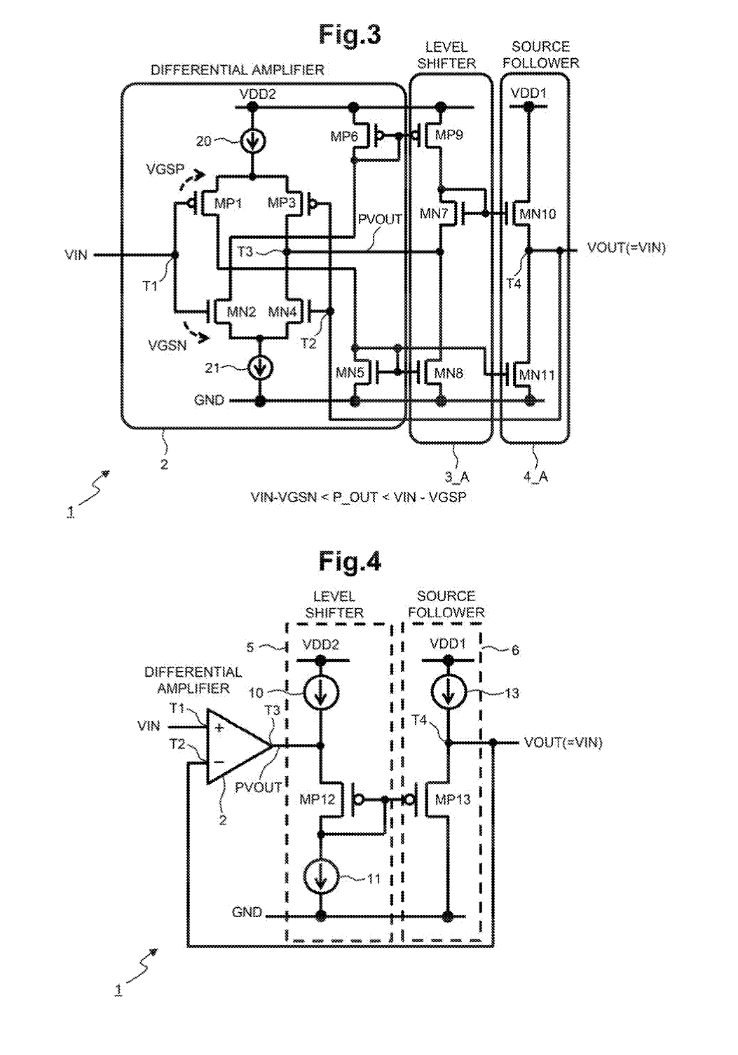

FIG. 3 shows an example in which current sources of the level shifter 3 and source follower 4 in FIGS. 1 and 2 are embodied. The level shifter 3_A has: an n-channel type eighth current source transistor MN8 sharing a gate with the fifth load transistor MNS, and linked to the ground GND; a p-channel type ninth current source transistor MP9 sharing a gate with the sixth load transistor MP6, and linked to the source voltage VDD2; and an n-channel type seventh transistor MN7 disposed between the eighth current source transistor MN8 and the ninth current source transistor MP9. The drain of the seventh transistor MN7 is connected to its own gate. The source of the seventh transistor MN7 is connected to the amplifier output terminal T3. The drain voltage (gate voltage) of the seventh transistor MN7 makes the shift voltage. The eighth current source transistor MN8 and the ninth current source transistor MP9 each form a current mirror circuit in combination with the corresponding fifth load transistor MN5 and sixth load transistor MP6 of the differential amplifier 2, which works so as to increase the amplification factor of the differential amplifier 2.

The source follower 4_A includes: an n-channel type eleventh current source transistor MN11 sharing the gate with the fifth load transistor MN5, and linked to the ground GND; and an n-channel type tenth transistor MN10 with the source connected to the drain of the eleventh current source transistor MN11. The gate of the tenth transistor MN10 is commonly connected with the gate of the seventh transistor MN7; and the source of the tenth transistor MN10 makes the follower output terminal T4.

With the series regulator 1 arranged as described above, the one-step amplification differential amplifier 2 is smaller in amplifying action delay owing to a load fluctuation in comparison to an amplifier of two-step amplification. Further, the differential amplifier 2 has a DC operation point at which the error of the output voltage PVOUT at the amplifier output terminal T3 to the input voltage VIN to the non-inverting input terminal T1 is equal to or lower than a voltage between the gate and source of the input transistor. The DC operation point is less prone to being fluctuated by input voltages to the input terminals T1 and T2, and the source voltage VDD2. So, even the one-step amplification differential amplifier 2 can output the voltage PVOUT small in error to the input voltage VIN as the reference voltage at the amplifier output terminal T3. The voltage VOUT at the follower output terminal T4 is obtained as a voltage after passing through the level shifter and the source follower, which is substantially identical to the voltage PVOUT at the amplifier output terminal T3. In this way, a desired voltage small in error to the reference voltage VIN can be output at the follower output terminal T4. Therefore, the output voltage VOUT of the series regulator 1 can be stably formed with high-speed load responsiveness without externally adding a large stabilization capacitance to a semiconductor integrated circuit including the series regulator 1 as a power supply circuit. The stabilization capacitance connected to the follower output terminal can be made smaller infinitely. So, the stabilization capacitance can be provided in the semiconductor integrated circuit, and the differential amplifier 2 serves to achieve a low power consumption because of being an amplifier of one-step amplification.

FIG. 10 shows, by example, the difference in frequency characteristic of the output voltage VOUT between the series regulator 1 of FIG. 3, and a series regulator arranged by use of a two-step amplifier under the condition of no difference in circuit's electric current consumption or load. While in the series regulator arranged by use of a two-step amplification amplifier, the DC amplification factor is as high as 70 dB because of using the two-step amplification amplifier, the frequency band is 1.1 MHz smaller than 4.0 MHz which is a frequency band of the series regulator 1 of FIG. 3. In short, the series regulator 1 of FIG. 3 according to the disclosure has a higher cutoff frequency. It is clear from this point that the series regulator 1 of FIG. 3 according to the disclosure had the advantage over a series regulator arranged by a two-step amplifier in high-speed responsiveness.

Although no special restriction is intended, the operation power source voltage VDD2, which is the high-potential side power source of the differential amplifier 2 and level shifter 3, and the operation power source voltage VDD1 on the side of the high-potential power source of the source follower 4 satisfy the following relation: VDD2>VDD1. This makes possible to widen the voltage range of the output voltage VOUT of the source follower 4.

FIG. 4 shows a sink-driving type series regulator, which is another embodiment of the series regulator of the disclosure. The series regulator 1 of FIG. 4 has: a differential amplifier 2; a level shifter 5 including a p-channel type twelfth transistor MP12 as an embodiment of the level shift transistor with its drain connected to the gate; and a source follower 6 including a p-channel type thirteenth transistor MP13 as an embodiment of the output transistor.

The level shifter 5 includes a p-channel type twelfth transistor MP12 disposed between a current source 10 linked to the high-potential side source voltage VDD2, and a current source 11 linked to the low-potential side source voltage GND; the drain of the twelfth transistor MP12 is connected to its own gate. The source of the twelfth transistor MP12 is connected to the amplifier output terminal T3; and the drain voltage (gate voltage) of the twelfth transistor makes a shift voltage. The level shifter 5 shifts down the voltage PVOUT at the amplifier output terminal T3 by a voltage between the gate and source of the twelfth transistor, and outputs the resultant voltage.

The source follower 6 includes a p-channel type thirteenth transistor MP13 with its source connected to a current source 13 linked to the high-potential side source voltage VDD1; the thirteenth transistor MP13 has a gate commonly connected with the gate of the twelfth transistor MP12; and the source of the thirteenth transistor MP13 makes the follower output terminal T4. The level shifter 5 is provided to make the output voltage VOUT of the source follower 6 identical to the voltage PVOUT at the amplifier output terminal T3 of the differential amplifier 2. The source follower 6 receives, at its gate, a drain voltage of the twelfth transistor MP12 of the level shifter 5. The source follower is capable of outputting a voltage incident to the voltage PVOUT at the amplifier output terminal T3 at the source of the thirteenth MOS transistor MP13. This source follower is suitable for a case in which an output function of a so-called sink-driving type is required.

The differential amplifier 2 is a one-step amplifier, which is the same as that described above. The differential amplifier has a DC operation point at which the error of the output voltage PVOUT at the amplifier output terminal T3 to the input voltage VIN to the non-inverting input terminal T1 is equal to or less than a voltage between the gate and source of the input transistor. The follower output terminal T4 of the source follower is feedback-connected to the inverting input terminal T2.

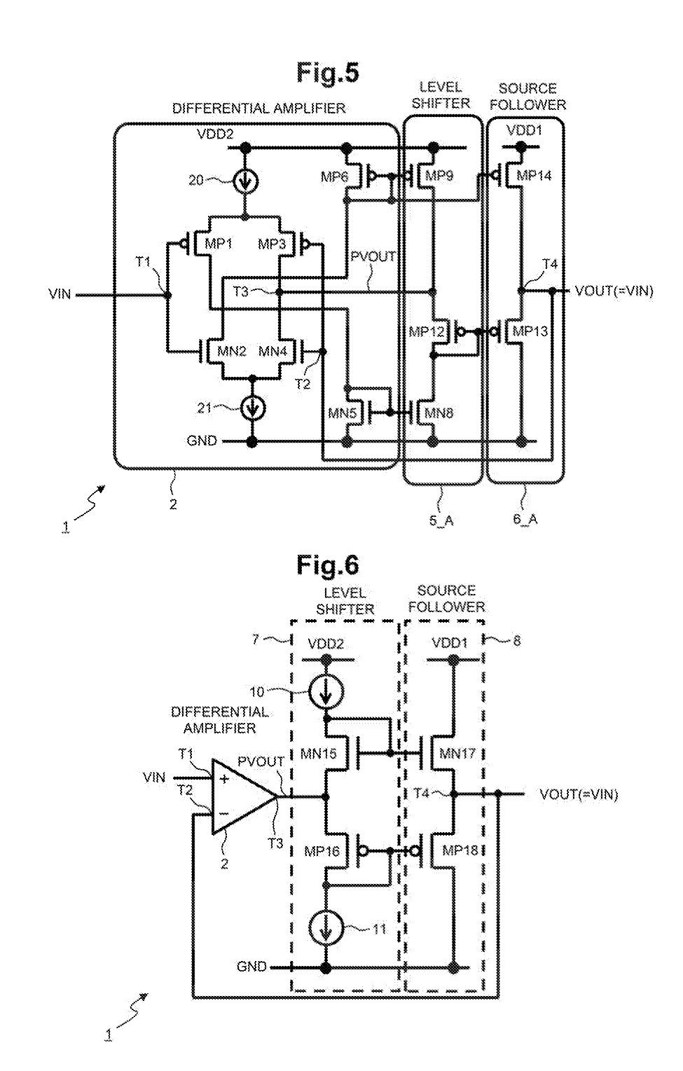

FIG. 5 shows an example in which the current sources of the level shifter 3 and source follower 4 in FIG. 4 are embodied. The level shifter 5_A has: an n-channel type eighth current source transistor MN8 sharing a gate with the fifth load transistor MNS, and linked to the ground GND; a p-channel type ninth current source transistor MP9 sharing a gate with the sixth load transistor MP6, and linked to the high-potential side source voltage VDD2; and a p-channel type twelfth transistor MP12 disposed between the eighth current source transistor MN8 and the ninth current source transistor MP9. The twelfth transistor MP12 has a drain connected to its own gate, and a source to which the amplifier output terminal T3 is connected; a drain voltage of the twelfth transistor MP12 makes the shift voltage. The function of increasing the amplification factor of the differential amplifier 2 by the eighth current source transistor MN8 and the ninth current source transistor MP9 is the same as that described with reference to FIG. 3.

The source follower 6_A includes: a p-channel type fourteenth current source transistor MP14 sharing a gate with the sixth load transistor MP6, and linked to the high-potential side source voltage VDD1; and a p-channel type thirteenth transistor MP13 having a source connected to the drain of the fourteenth current source transistor MP14. The gate of the thirteenth transistor is commonly connected to the gate of the twelfth transistor MP12. The source of the thirteenth transistor MP13 makes the follower output terminal T4.

The series regulator shown in FIGS. 4 and 5 is different from the series regulator shown in FIGS. 1 to 3 in that it is suitable for the sink driving. The effect other than this is the same and therefore, the detailed description thereof is omitted here.

FIG. 6 shows a series regulator of a double driving type arranged by combination of source driving and sink driving, which is still another embodiment of the series regulator of the disclosure. The series regulator 1 of FIG. 6 includes: a differential amplifier 2; a level shifter 5 including, as embodiments of a diode-connected level shift transistor having a drain connected to a gate, an n-channel type fifteenth transistor MN15 and a p-channel type sixteenth transistor MP16, which are connected in series to each other through their source common to them; and a source follower 8 including, as embodiments of an output transistor, an n-channel type seventeenth transistor MN17 and a p-channel type eighteenth transistor MP18, which are connected in series to each other through their source common to them.

The level shifter 7 has the n-channel type fifteenth transistor MN15 and the p-channel type sixteenth transistor MP16 which are connected in series to each other through the source common to them between a current source 10 linked to the source voltage VDD2 on the high-potential side, and an a current source 11 linked to the ground GND on the low-potential side. The fifteenth transistor MN15 has a drain connected to its own gate; the sixteenth transistor MP16 has a drain connected to its own gate; and the amplifier output terminal T3 is connected to the common source of the fifteenth transistor MN15 and the sixteenth transistor MP16. A drain voltage of each of the fifteenth transistor MN15 and the sixteenth transistor MP16 is output as the shift voltage. The level shifter 7 outputs a voltage resulting from the upshift of the voltage PVOUT at the amplifier output terminal by a voltage between the gate and source of the fifteenth transistor MN15, and a voltage resulting from the downshift thereof by a voltage between the gate and source of the sixteenth transistor MP16.

The source follower 8 includes an n-channel type seventeenth transistor MN17 and a p-channel type eighteenth transistor MP18 which are connected in series to each other through a source common to them. The gate of the seventeenth transistor MN17 is connected to the gate of the fifteenth transistor MN15. The gate (drain) of the eighteenth transistor MP18 is connected to the gate (drain) of the sixteenth transistor MP16. The common source of the seventeenth transistor MN17 and the eighteenth transistor MP18 makes the follower output terminal T4. The level shifter 7 is provided to make the output voltage VOUT of the source follower 8 equal to the voltage PVOUT at the amplifier output terminal T3 of the differential amplifier 2. The seventeenth MOS transistor receives the drain voltage of the fifteenth transistor MN15 of the level shifter 7 at its gate, and outputs a voltage coincident with the voltage PVOUT at the amplifier output terminal T3 at its source; and the eighteenth MOS transistor receives the drain voltage of the sixteenth transistor MP16 of the level shifter 7 at its gate, and outputs a voltage coincident with the voltage PVOUT at the amplifier output terminal T3 at its source. The source follower 8 forms an output circuit having both of so-called source-driving and sink-driving functions. So, the series regulator is superior in responsiveness to a load fluctuation to a series regulator having an output characteristic according to only one of the sink-driving and source-driving functions.

The differential amplifier 2 is a one-step amplifier, which is the same as that described above. The differential amplifier has a DC operation point at which the error of the output voltage PVOUT at the amplifier output terminal T3 to the input voltage VIN to the non-inverting input terminal T1 is equal to or less than a voltage between the gate and source of the input transistor; the follower output terminal T4 of the source follower is feedback-connected to the inverting input terminal T2.

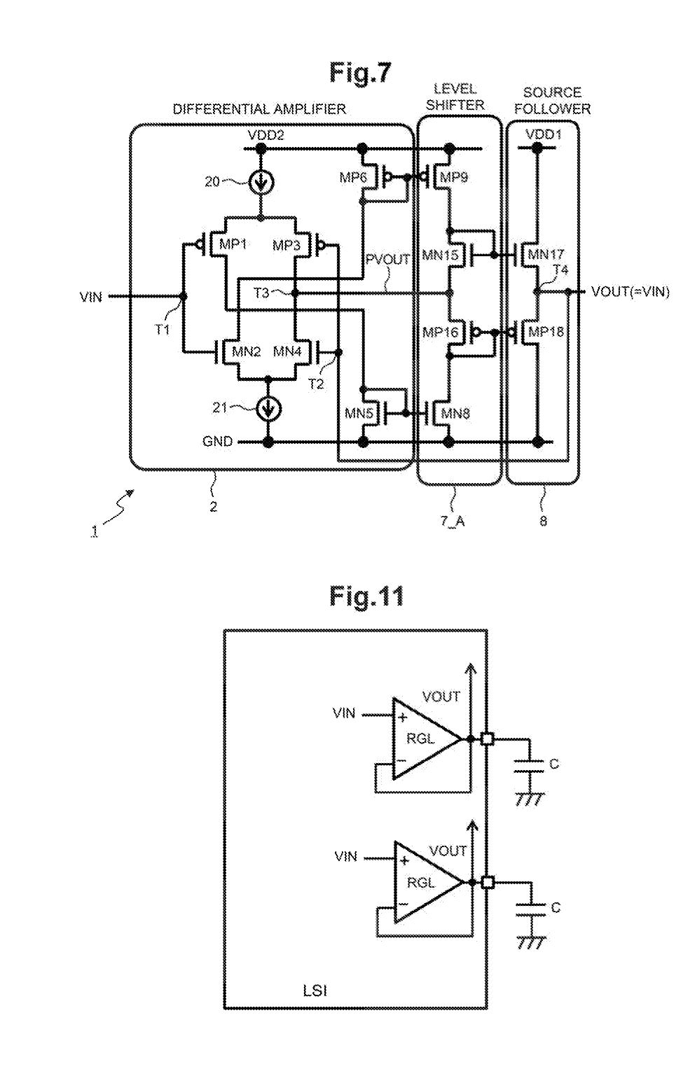

FIG. 7 shows an example in which the current sources of the level shifter 7 of FIG. 6 are embodied. The level shifter 7_A includes: an n-channel type eighth current source transistor MN8 sharing a gate with the fifth load transistor MN5, and linked to the ground GND; a p-channel type ninth current source transistor MP9 sharing a gate with the sixth load transistor MP6, and linked to the high-potential side source voltage VDD2; and an n-channel type fifteenth transistor MN15 and a p-channel type sixteenth transistor MP16 which are connected in series to each other through a source common to them between the eighth current source transistor MN8 and the ninth current source transistor MP9. In the level shifter, the fifteenth transistor MN15 has a drain connected to its own gate; the sixteenth transistor MP16 has a drain connected to its own gate; and the amplifier output terminal T3 is connected to the common source of the fifteenth transistor MN15 and the sixteenth transistor MP16. A drain voltage of each of the fifteenth transistor MN15 and the sixteenth transistor MP16 is output as the shift voltage. The level shifter 7_A outputs a voltage resulting from the upshift of the voltage PVOUT at the amplifier output terminal T3 by a voltage between the gate and source of the fifteenth transistor MN15, and a voltage resulting from the downshift thereof by a voltage between the gate and source of the sixteenth transistor MP16. The function of increasing the amplification factor of the differential amplifier 2 by the eighth current source transistor MN8 and the ninth current source transistor MP9 is the same as that described with reference to FIG. 3.

The series regulator shown in FIGS. 6 and 7 is different from the series regulator shown in FIGS. 1 to 3 in that it is suitable for both of source driving and sink driving. The effect other than this is the same and therefore, the detailed description thereof is omitted here.

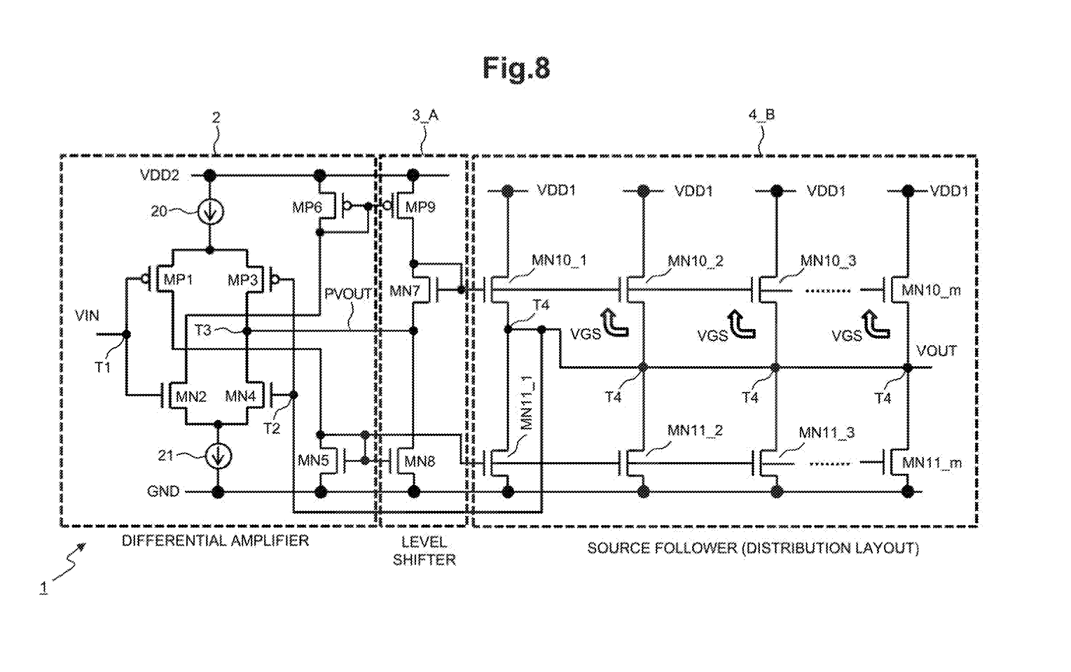

FIG. 8 shows, as a still another embodiment of the series regulator of the disclosure, a series regulator in which the source follower is distributed in function. What is taken as an example here is a series regulator having a differential amplifier 2 and a level shifter 3_A which are the same as those in the embodiment of FIG. 3. The source follower 4_B shown in the diagram has a plurality of output transistors MN10_1 to MN10_m. The plurality of output transistors MN10_1 to MN10_m have a common gate, and they receive a shift voltage from the level shifter at the common gate. The output transistors MN10-1 to MN10_m have a common source, which makes the follower output terminal T4. That is, the source follower 4_B is provided with: n-channel type eleventh current source transistors MN11_1 to MN11_m sharing their gate with the fifth load transistor MN5, and linked to the ground GND; and the n-channel type tenth transistors MN10_1 to MN10_m of which the sources are connected to drains of the eleventh current source transistors MN11_1 to MN11_m respectively. The gates of the tenth transistors MN10_1 to MN10_m are commonly connected to the gate of the seventh transistor MN7, and the sources of the tenth transistors MN10_1 to MN10_m make the follower output terminal T4.

According to this, the voltage VOUT at the follower output terminal T4 depends on gate-source voltages of the output transistors MN10_1 to MN10_m, and it is not affected by a voltage drop in the source voltage VDD1 caused by the wiring resistance of a power source line. Therefore, even the tenth transistors MN10_1 to MN10_m serving as output transistors respectively, which are distributed in the source follower 4_B as required do not influence the performance of supplying a power source.

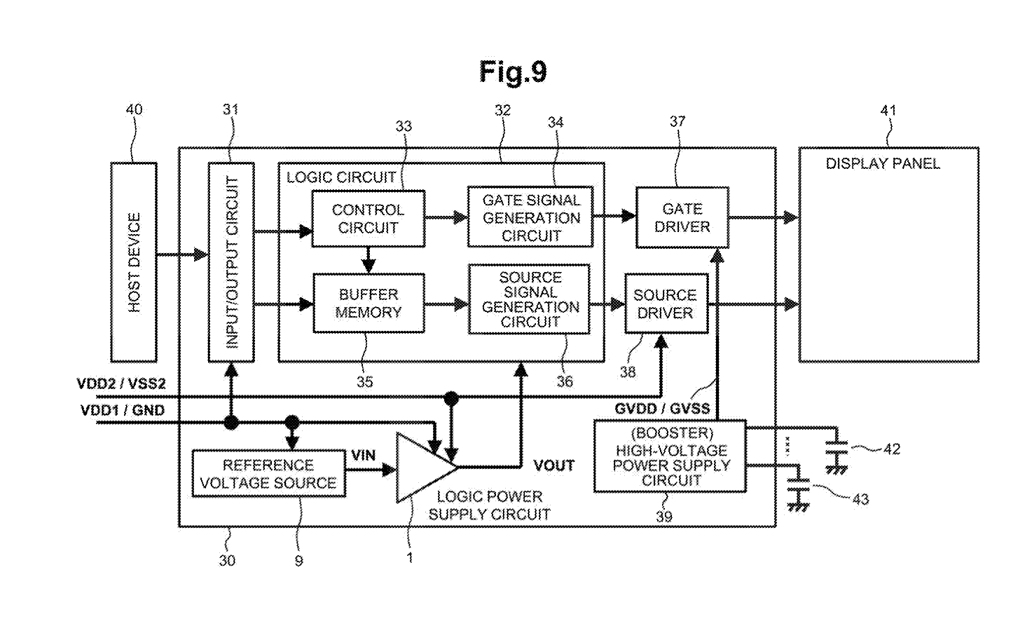

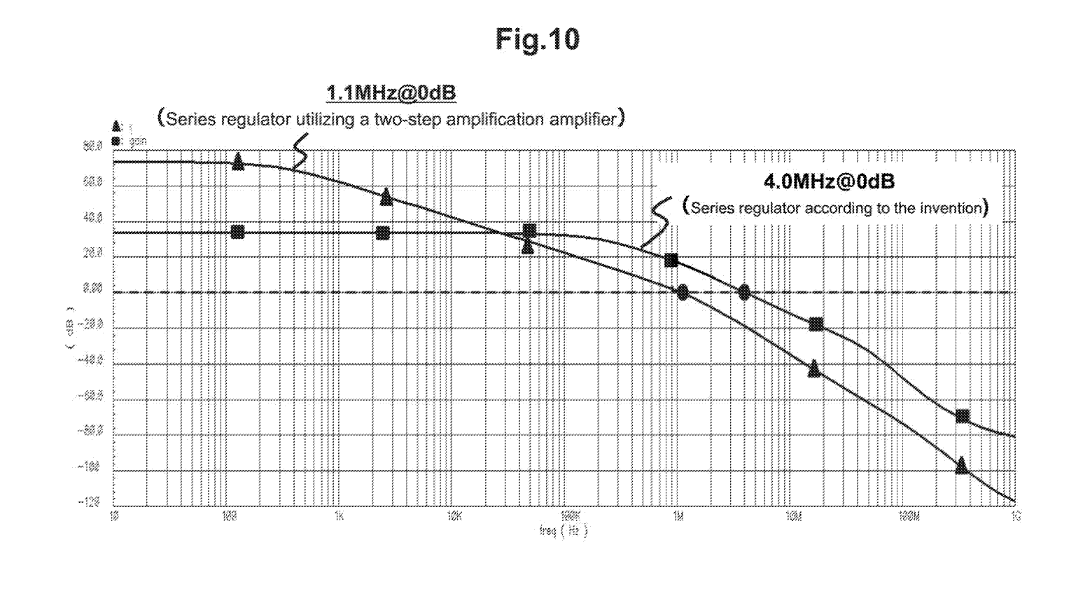

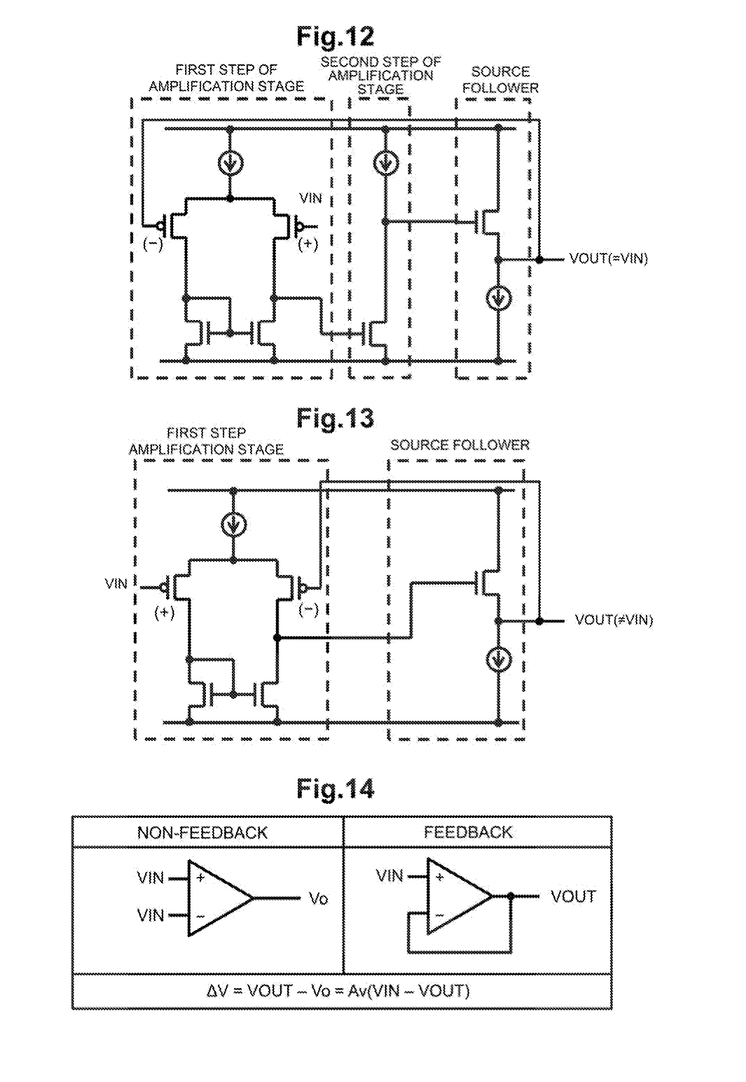

FIG. 9 shows an embodiment of a display driver including a logic power supply circuit to which the series regulator 1 described above is applied. In FIG. 9, the numeral 30 represents a display driver, 41 represents a display panel of liquid crystal or the like, and 40 represents a host device. Although no special restriction is intended, the display driver 30 is formed as a semiconductor integrated circuit on a semiconductor substrate (chip) of single crystal silicon or the like by a known CMOS integrated circuit manufacturing technique or the like.

The host device 40 supplies display data, a display control command, and others to the display driver 30. In application to e.g. a portable terminal device(terminal device), the host device 2 includes a communication part connectable to a mobile communication network or the like, a protocol processor which performs a communication protocol process with the communication part, an application processor which controls the protocol processor and various data processes, and peripheral devices including an auxiliary storage and an external interface circuit. The host device 2 is not limited to this, and it may be any of various electronic devices which use the display panel 41.

While not particularly shown in the diagram, the display panel 41 has a plurality of display elements 42 formed like a matrix on a glass substrate; each display element has a series-connected thin film transistor, liquid crystal located between liquid crystal electrodes and a capacitance; and a source line is coupled to the source of each thin film transistor 43 and a gate line is connected to the gate of each thin film transistor. The lines formed by the plurality of display elements, corresponding to gate lines, each make a display line. The thin film transistors of the plurality of display elements are turned on in units of the display line. In this way, a display line is selected; gradation drive signals according to display data are provided to the display elements from the source lines in each select period (horizontal display period) of the display line. Each gradation drive signal is a voltage signal selected from a plurality of gradation voltages according to the display data.

The display driver 30 has: an input/output circuit 31 interfaced to the host device 40; a logic circuit 32 operable to perform display control; a gate driver 37; and a source driver 38. Further, as constituent parts in connection with its power source, the display driver has: a reference voltage source 9; a series regulator 1 as a logic power supply circuit; and a high-voltage power supply circuit 39 such as a booster. To the high-voltage power supply circuit 39, stabilization capacitances 42, 43 for stabilizing a boosted voltage are connected as additional parts (so-called external parts) outside the display driver 30. To the series regulator 1, a stabilization capacitance, e.g. an additional part described above is not connected.

Although no special restriction is intended, the logic circuit 32 includes: a control circuit 33; a buffer memory 35; a gate signal generation circuit 34; and a source signal generation circuit 36.

The input/output circuit 31 accepts the input of control data and display data from the host device 40. Then, the control circuit 33 receives the control data and the buffer memory 35 receives the display data. The control circuit 33 controls the action of the display driver 30 based on the input control data. The gate signal generation circuit 34 generates gate select signals for sequentially selecting the display lines in synchronization with the display timing, and the source signal generation circuit 36 produces source signals for driving the source lines based on the display data in the buffer memory 35. The gate driver 37 performs the control for selecting the display lines based on the gate select signals, and the source driver 38 drives the source lines of the display panel 41 according to the source signals in synchronization with this. Thus, brightness signals are sequentially written into pixels of each display line in synchronization with a horizontal synchronization period in units of the frame in the display panel 41.

The operation power sources for the individual parts are as follows. The external power sources on the high-potential side are source voltages VDD1 and VDD2, and those on the low-potential side are the ground GND and the power source VSS2, which are supplied from an external power supply circuit (not shown). It is supposed here that these power sources have the following relations: VDD2>VDD1; and VSS2□GND. The input/output circuit 31 is supplied with the source voltage VDD1 and the ground GND; the source driver 38 is supplied with the source voltage VDD2 and the ground VSS2; and the gate driver 39 is supplied with boost voltages GVDD and GVSS from the high-voltage power supply circuit 39. The operation power source of the high-voltage power supply circuit 39 is made e.g. VDD2 and VSS2.

The operation power source of the logic circuit is VOUT on the high-potential side, which is formed by the series regulator 1, and GND on the low-potential side. The reference voltage source 9 operable to form the reference voltage VIN to be supplied to the series regulator 1 uses the source voltage VDD1 and the ground GND as its operation power source. As described above, the series regulator 1 is supplied with the source voltages VDD1, VDD2 and the ground GND.

As described above, the series regulator 1 is smaller in amplifying action delay owing to load fluctuation in comparison to a series regulator for which two-step amplification is adopted and is capable of outputting a voltage VOUT small in error to the reference voltage VIN. Therefore, the output voltage VOUT of the series regulator 1 can be stably formed with a high-speed load responsiveness without the need for adding a large stabilization capacitance outside the display driver 30 including the series regulator 1 as a logic power supply circuit. A stabilization capacitance connected to the follower output terminal T4 can be made smaller infinitely. So, the stabilization capacitance can be provided in the display driver 30. The display driver 30 originally needs a source voltage VDD2 higher, in voltage, than a standard source voltage VDD1 because a relatively high drive voltage is required for source driving. Therefore, the operation power source VDD2 can be diverted to the operation power source for the differential amplifier 2 and the source follower 3, 3_A, 6, 6_A, 8 as a power source higher, in level, than the operation power source VDD1 for the source follower 4, 4_A, 54_B, 5, 5_A, 7, 7_A, and the reference voltage source 9; it is not necessary to particularly prepare an operation power source such as VDD2. Especially, by adopting a series regulator in which the output transistors MN10_1 to MN10_m of the source follower are distributed around the logic circuit 32 as described with reference to FIG. 8, the source voltage VOUT can be stably supplied to each circuit part without an undesired voltage drop even in the logic circuit 32 large in circuit scale.

While the disclosure has been described based on the embodiments concretely, it is not limited to the embodiments. It is obvious that various changes or modifications may be made without departing from the subject matter thereof.

For instance, the differential amplifier, the level shifter, and the source follower are not limited to the above circuit structure. For instance, the first load is not limited to the fifth load transistor MNS, and the second load is not limited to the sixth load transistor MP6. As to the current sources, they are not limited to transistors in a current-mirror form. In addition, the transistor size of the level shift transistor such as MN7 in the level shifter, and the transistor size of an output transistor such as MN10 in the source follower are not limited to be identical to each other, and they may be arranged to differ from each other. This also applies to the transistor size of each current source.

The semiconductor integrated circuit is not limited to a display driver, and it can be widely applied to devices arranged on condition that a series regulator is provided therein. The series regulator is not limited to the application to a power supply circuit for a logic circuit, and it can be applied to a circuit operable to supply a circuit relatively large in load fluctuation with a power source or a drive voltage. Further, it is not excluded to provide the display driver together with a touch panel controller operable to perform not only display control, but also the touch control of a touch panel, and a subprocessor operable to perform a local operation control, etc.

What is claimed is:

1. A series regulator comprising:
a differential amplifier;
a level shifter including a level shift transistor with a drain connected to its own gate; and
a source follower including an output transistor,
wherein the differential amplifier includes an amplification stage having a non-inverting input terminal for inputting a reference voltage, an inverting input terminal for inputting a feedback voltage, and an amplifier output terminal,
the differential amplifier has a DC operation point at which an error of an output voltage at the amplifier output terminal to an input voltage to the non-inverting input terminal is equal to or less than a voltage between a gate and a source of an input transistor, and a follower output terminal of the source follower is feedback-connected to the inverting input terminal,
the level shifter accepts input of an output voltage from the amplifier output terminal at a source of the level shift transistor, and outputs a gate voltage thereof as a shift voltage, and
the source follower receives the shift voltage from the level shifter at a gate of the output transistor, and a source of the output transistor makes the follower output terminal.

2. The series regulator according to claim 1, wherein the differential amplifier has a p-channel type first input transistor and an n-channel type second input transistor of which gates are commonly connected to the non-inverting input terminal,
a p-channel type third feedback input transistor and an n-channel type fourth feedback input transistor of which gates are commonly connected to the inverting input terminal,
a first load connected to a drain of the first input transistor, and linked to a low-potential side power source, and
a second load connected to a drain of the second input transistor, and linked to a high-potential side power source, and
a common drain of the third and fourth feedback input transistors makes the amplifier output terminal.

3. The series regulator according to claim 1, wherein the differential amplifier has a p-channel type first input transistor and an n-channel type second input transistor of which gates are commonly connected to the non-inverting input terminal,
a p-channel type third input transistor and an n-channel type fourth input transistor of which gates are commonly connected to the inverting input terminal,
a diode-connected n-channel type fifth load transistor connected to a drain of the first input transistor, and linked to a low-potential side power source, and
a diode-connected p-channel type sixth load transistor connected to a drain of the second input transistor and linked to a high-potential side power source, and
a common drain of the third and fourth feedback input transistor makes the amplifier output terminal.

4. The series regulator according to claim 2, wherein the level shifter includes an n-channel type seventh transistor disposed between a current source linked to a high-potential side power source, and a current source linked to a low-potential side power source,
the seventh transistor has a drain connected to its own gate, and a source connected to the amplifier output terminal, and
a drain voltage of the seventh transistor makes the shift voltage.

5. The series regulator according to claim 3, wherein the level shifter includes an n-channel type eighth current source transistor sharing a gate with the fifth load transistor, and linked to a low-potential side power source, a p-channel type ninth current source transistor sharing a gate with the sixth load transistor, and linked to a high-potential side power source, and an n-channel type seventh transistor disposed between the eighth and ninth current source transistors,
the seventh transistor has a drain connected to its own gate, and a source connected to the amplifier output terminal, and
a drain voltage of the seventh transistor makes the shift voltage.

6. The series regulator according to claim 4, wherein the source follower includes an n-channel type tenth transistor having a source connected to a current source linked to a low-potential side power source,
the tenth transistor has a gate commonly connected with the gate of the seventh transistor, and
the source of the tenth transistor makes the follower output terminal.

7. The series regulator according to claim 5, wherein the source follower includes an n-channel type eleventh current source transistor sharing a gate with the fifth load transistor, and linked to the low-potential side power source; and
an n-channel type tenth transistor having a source connected to a drain of the eleventh current source transistor,
the tenth transistor has a gate commonly connected with the gate of the seventh transistor, and
the source of the tenth transistor makes the follower output terminal.

8. The series regulator according to claim 2, wherein the level shifter includes a p-channel type twelfth transistor disposed between a current source linked to a high-potential side power source, and a current source linked to a low-potential side power source,
the twelfth transistor has a drain connected to its own gate, and a source connected to the amplifier output terminal, and
a drain voltage of the twelfth transistor makes the shift voltage.

9. The series regulator according to claim 3, wherein the level shifter includes an n-channel type eighth current source transistor sharing a gate with the fifth load transistor, and linked to a low-potential side power source,
a p-channel type ninth current source transistor sharing a gate with the sixth load transistor, and linked to a high-potential side power source, and
a p-channel type twelfth transistor disposed between the eighth and ninth current source transistors,
the twelfth transistor has a drain connected to its own gate, and a source connected to the amplifier output terminal, and
a drain voltage of the twelfth transistor makes the shift voltage.

10. The series regulator according to claim 8, wherein the source follower includes a p-channel type thirteenth transistor having a source connected to a current source linked to a high-potential side power source,
the thirteenth transistor has a gate commonly connected with the gate of the twelfth transistor, and
the source of the thirteenth transistor makes the follower output terminal.

11. The series regulator according to claim 9, wherein the source follower includes a p-channel type fourteenth current source transistor sharing a gate with the sixth load transistor, and linked to a high-potential side power source, and
a p-channel type thirteenth transistor having a source connected to a drain of the fourteenth current source transistor,
the thirteenth transistor has a gate commonly connected with the gate of the twelfth transistor, and
the source of the thirteenth transistor makes the follower output terminal.

12. The series regulator according to claim 2, wherein the level shifter includes an n-channel type fifteenth transistor and a p-channel type sixteenth transistor which are connected in series to each other through a source common thereto between a current source linked to a high-potential side power source and a current source linked to a low-potential side power source,
the fifteenth transistor has a drain connected to its own gate,
the sixteenth transistor has a drain connected to its own gate,
the common source of the fifteenth and sixteenth transistors is connected to the amplifier output terminal, and
a drain voltage of each of the fifteenth and sixteenth transistors makes the shift voltage.

13. The series regulator according to claim 3, wherein the level shifter includes an n-channel type eighth current source transistor sharing a gate with the fifth load transistor, and linked to a low-potential side power source,
a p-channel type ninth current source transistor sharing a gate with the sixth load transistor, and linked to a high-potential side power source, and
an n-channel type fifteenth transistor and a p-channel type sixteenth transistor which are connected in series to each other through a source common thereto between the eighth and ninth current source transistors,
the fifteenth transistor has a drain connected to its own gate,
the sixteenth transistor has a drain connected to its own gate,
the common source of the fifteenth and sixteenth transistors is connected to the amplifier output terminal, and
a drain voltage of each of the fifteenth and sixteenth transistors makes the shift voltage.

14. The series regulator according to claim 12, wherein the source follower includes an n-channel type seventeenth transistor and a p-channel type eighteenth transistor which are connected in series to each other through a source common thereto,
the seventeenth transistor is connected to the gate of the fifteenth transistor,
the eighteenth transistor is connected to the gate of the sixteenth transistor, and
the common source of the seventeenth and eighteenth transistors makes the follower output terminal.

15. The series regulator according to claim 13, wherein the source follower includes an n-channel type seventeenth transistor and a p-channel type eighteenth transistor which are connected in series to each other through a source common thereto,
the seventeenth transistor is connected to the gate of the fifteenth transistor,
the eighteenth transistor is connected to the gate of the sixteenth transistor, and
the common source of the seventeenth and eighteenth transistors makes the follower output terminal.

16. The series regulator according to claim 1, wherein the output transistor of the source follower includes a plurality of output transistors having a common gate,
the plurality of output transistors receive the shift voltage from the level shifter at the common gate, and
a common source of the plurality of output transistors makes the follower output terminal.

17. The series regulator according to claim 1, wherein a source voltage of a high-potential side power source of the differential amplifier and the level shifter is made higher than a source voltage of a high-potential side power source of the source follower.

18. A semiconductor integrated circuit comprising:
a logic circuit on a semiconductor substrate; and
a series regulator for supplying an operation power source to the logic circuit on the semiconductor substrate,
wherein the series regulator includes a differential amplifier, a level shifter including a level shift transistor with a drain connected to its own gate, and a source follower including an output transistor,
the differential amplifier includes an amplification stage having a non-inverting input terminal for inputting a reference voltage, an inverting input terminal for inputting a feedback voltage, and an amplifier output terminal,
the differential amplifier has a DC operation point at which an error of an output voltage at the amplifier output terminal to an input voltage to the non-inverting input terminal is equal to or less than a voltage between a gate and a source of an input transistor, and a follower output terminal of the source follower is feedback-connected to the inverting input terminal,
the level shifter accepts input of an output voltage from the amplifier output terminal at a source of the level shift transistor, and outputs a gate voltage thereof as a shift voltage,
the source follower receives the shift voltage from the level shifter at a gate of the output transistor, and a source of the output transistor makes the follower output terminal, and
a voltage at the follower output terminal makes the operation power source.

19. The semiconductor integrated circuit according to claim 18, wherein the differential amplifier has a p-channel type first input transistor and an n-channel type second input transistor of which gates are commonly connected to the non-inverting input terminal,
a p-channel type third input transistor and an n-channel type fourth input transistor of which gates are commonly connected to the inverting input terminal,
a first load connected to a drain of the first input transistor, and linked to a low-potential side power source, and
a second load connected to a drain of the second input transistor, and linked to a high-potential side power source, and
a common drain of the third and fourth feedback input transistors makes the amplifier output terminal.

20. The semiconductor integrated circuit according to claim 18, wherein the output transistor of the source follower includes a plurality of output transistors having a common gate,
the plurality of output transistors receive the shift voltage from the level shifter at the common gate, and
a common source of the plurality of output transistors makes the follower output terminal.
